(19) United States
(12) Patent Application Publication
(10) Pub. No.: US 2019/0245526 A1
(43) Pub. Date: Aug. 8, 2019

(54) LEVEL SHIFT CIRCUIT

(71) Applicants: Kabushiki Kaisha Toshiba, Tokyo (JP); Toshiba Electronic Devices & Storage Corporation, Tokyo (JP)

(72) Inventors: Youichi Satou, Kawasaki Kanagawa (JP); Masazumi Shiochi, Fuchu Tokyo (JP); Satoko Susa, Ota Tokyo (JP)

(21) Appl. No.: 16/118,570

(22) Filed: Aug. 31, 2018

(30) Foreign Application Priority Data
Feb. 8, 2018 (JP) 2018-020664

(51) Int. Cl. H03K 3/356; H03K 3/011

(52) U.S. Cl. CPC H03K 3/356113; H01L 27/092; H03K 3/011

(57) ABSTRACT

According to one embodiment, a level shift, circuit includes first to sixth transistors, is supplied with a power supply voltage, boosts the voltage of an input signal, and outputs an output signal whose high-level voltage is at the power source voltage. A first control voltage is applied to a control terminal of the first transistor and the second transistor. A second control voltage is applied to a control terminal of the third transistor and the fourth transistor. The fifth transistor has a control terminal to which an input signal is inputted. The sixth transistor has a control terminal to which an inverted signal of the input signal is inputted.

### CROSS REFERENCE TO RELATED APPLICATION

This application is based upon and claims the benefit, of priority from the prior Japanese Patent Application No. 2018-0206646, filed on Feb. 8, 2018, the entire contents of which are incorporated herein by reference.

### FIELD

Embodiments discussed herein are related to a level shift circuit,

### BACKGROUND

A level shift circuit that boosts the voltage of a signal is applied to various semiconductor integrated circuits provided with an input/output interface, a bus, and the like. The level shift circuit is generally constructed using CMOS technology configured with P-channel MOS transistors and N-channel MOS transistors. The level shift circuit is constructed using miniaturized. CMOS technology to achieve high speed operation. In CMOS technology, as technology nodes advance more (i.e., miniaturization advances more), the withstand voltage between the terminals of a MOS transistor becomes lower.

When the level shift circuit is supplied with a power supply voltage, boosts the voltage of an input signal, and outputs an output signal whose signal voltage level is high, a voltage exceeding an allowable withstand voltage value is applied between the terminals of a MOS transistor during operation. When a voltage applied exceeds a withstand voltage between the terminals of a MOS transistor, the level shift circuit may break or degrade in reliability.

### BRIEF DESCRIPTION OF THE DRAWINGS

FIG. 1 is a circuit diagram showing a level shift circuit according to a first embodiment;

FIG. 2 is a circuit diagram showing a level shift circuit according to a first modification;

FIG. 3 is a circuit diagram showing a level shift circuit according to a second embodiment;

FIG. 4 is a diagram showing signal waveforms at a node N4 and a node N5 of the level shift circuit according to the second embodiment;

FIG. 5A is a diagram showing falls of the signal waveforms in FIG. 4, and FIG. 5B is a diagram showing a change in voltage between the node N4 and the node N5 at the falls of the signal waveforms in FIG. 4;

FIG. 6A is a diagram showing rises of the signal waveforms in FIG. 4, and FIG. 6B is a diagram showing a change in the voltage between the node N4 and the node N5 at the rises of the signal waveforms in FIG. 4;

FIG. 7 is a circuit diagram showing a level shift circuit according to a third embodiment;

FIG. 8 is a circuit diagram showing a level shift circuit according to a fourth embodiment.;

FIG. 9 is a circuit diagram showing a level shift circuit according to a fifth embodiment;

FIG. 10 is a circuit diagram showing a level shift circuit, according to a sixth embodiment;

FIG. 11 is a circuit diagram showing a level shift circuit according to a second modification;

FIG. 12 is a circuit diagram showing a level shift circuit according to a third modification; and

FIG. 13 is a circuit diagram showing a level shift circuit of a comparative example.

### DETAILED DESCRIPTION

According to one embodiment, a level shift circuit includes first to sixth transistors, is supplied with a power supply voltage, boosts the voltage of an input signal, and outputs an output signal whose high-level voltage is at the power source voltage. The first transistor has a control terminal to which a first control voltage is applied, and the second transistor has a control terminal to which the first control voltage is applied. The third transistor has a control terminal to which a second control voltage is applied and one end connected to one end of the first transistor. The fourth transistor has a control terminal to which the second control voltage is applied and one end connected to one end of the second transistor. The fifth transistor has a control terminal to which an input signal is inputted, one end connected to the other end of the third transistor, and the other end connected to ground potential. The sixth transistor has a control terminal to which an inverted signal of the input signal is inputted, one end connected to the other end of the fourth transistor, and the other end connected to the ground potential.

Further embodiments of the invention will be described with reference to the drawings. Throughout the drawings, the same reference numerals denote the same or like portions.

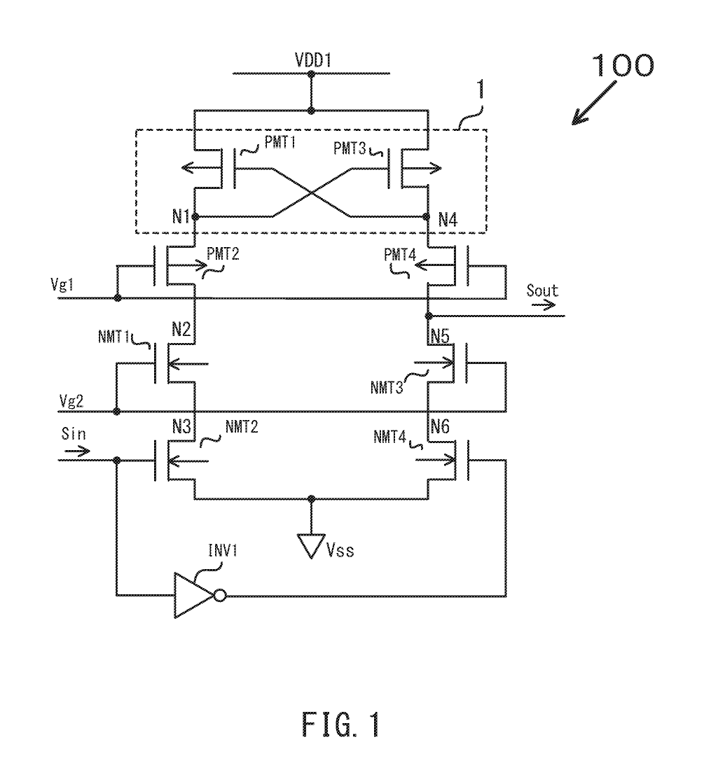

A level shift circuit according to a first embodiment will be described with reference to FIG. 1. FIG. 1 is a circuit diagram showing the level shift circuit.

The level shift circuit of the first embodiment is provided with two MOS transistors connected in series between a cross-coupled circuit and a MOS transistor to which an input signal is inputted and two MOS transistors connected in series between the cross-coupled circuit and a MOS transistor to which an inverted signal of the input signal is inputted. The first embodiment prevents a voltage exceeding an allowable value from being applied between the terminals of each MOS transistor.

As shown in FIG. 1, a level shift circuit 100 of the embodiment includes a cross-coupled circuit 1, an inverter INV1, MOS transistors NMT1 to NMT4, a MOS transistor PMT2, and a MOS transistor PMT4. The level shift circuit 100 is supplied with a power supply voltage Vdd1 from a power supply (high-potential power supply) VDD1, boosts the voltage of an input signal Sin, and outputs an output signal Sout whose high-level voltage is at the power supply voltage Vdd1. The level shift circuit is also called a level shifter.

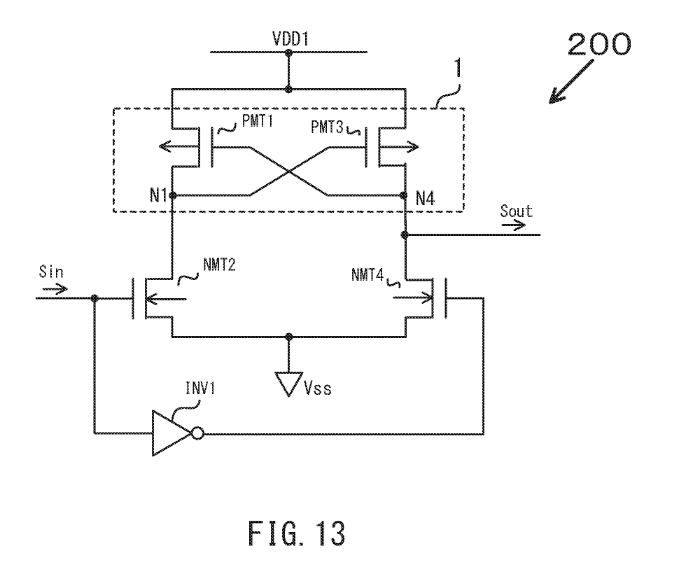

By contrast, a level shift circuit. 200 of a comparative example shown in FIG. 13 includes the cross-coupled circuit 1, the inverter INV1, the MOS transistor NMT2, and the MOS transistor NMT4, and is not provided with the MOS transistor NMT1, the MOS transistor NMT3, the MOS transistor PMT2, and the MOS transistor PMT4 in the level shift circuit 100 of the embodiment.

As shown in FIG. 1, the cross-coupled circuit 1 is configured with a MOS transistor PMT1 and a MOS transistor PMT3.

The MOS transistor PMT1 (first load transistor) is a P-channel MOS transistor. The MOS transistor PMT1 has one end (source) supplied with the power supply voltage Vdd1 from the power supply (high-potential power supply) VDD1 and the other end (drain) connected to a node N1.

The MOS transistor PMT3 (second load transistor) is a P-channel. MOS transistor. The MOS transistor PMT3 has one end (source) supplied with the power supply voltage Vdd1 from the power supply (high-potential power supply) VDD1, a control terminal (gate) connected to the node N1 and to the other end of the MOS transistor PMT1, and the other end (drain) connected to a control terminal of the MOS transistor PMT1 and to a node N4.

The MOS transistor PMT2 (first transistor) is a P-channel MOS transistor. The MOS transistor PMT2 has a source connected to the node N1, one end (drain) connected to a node N2, and a control terminal (gate) to which a control voltage Vg1 (first control voltage) is applied.

The MOS transistor PMT4 (second transistor) is a P-channel MOS transistor. The MOS transistor PMT4 has a source connected to the node N4, one end (drain) connected to a node N5, and a control terminal (gate) to which the control voltage Vg1 (first control voltage) is applied.

The MOS transistor NMT1 (third transistor) is an N-channel MOS transistor. The MOS transistor NMT1 has one end (drain) connected to the node N2, the other end (source) connected to a node N3, and a control terminal (gate) to which a control voltage Vg2 (second control voltage) is applied.

The MOS transistor NMT3 (fourth transistor) is an N-channel MOS transistor. The MOS transistor NMT3 has one end (drain) connected to the node N5, the other end (source) connected to a node N6, and a control terminal (gate) to which the control voltage Vg2 (the second control voltage) is applied.

The MOS transistor NMT2 (fifth transistor) is an N-channel MOS transistor. The MOS transistor NMT2 has one end (drain) connected to the node N3, the other end (source) connected to a ground potential (low-potential power supply) Vss, and a control terminal (gate) to which the input signal Sin is inputted.

The inverter INV1 has an input side connected to the control terminal (gate) of the MOS transistor NMT2 and an output side connected to the control terminal (gate) of the MOS transistor NMT4. The inverter INV1 inverts the input signal Sin.

The MOS transistor NMT4 (sixth transistor) is an N-channel MOS transistor. The MOS transistor NMT4 has one end (drain) connected to the node N6, the other end (source) connected to the ground potential (low-potential power supply) Vss, and a control terminal (gate) to which an inverted signal of the input signal Sin is inputted.

The output signal Sout obtained by boosting of the signal voltage of the input signal Sin is outputted from the node N5 (at the one-end side of the MOS transistor NMT3 (the fourth transistor)). The high-level voltage of the output signal Sout is at the power supply voltage Vdd1.

It is assumed here that the power supply voltage Vdd1 is set to 3.3 V and the high-level voltage of the input signal Sin is set to 1.5 V. The low-level voltage of the input signal Sin is at the ground potential Vss (0 (zero) V). The control voltage Vg2 (second control voltage) is set to be higher than the control voltage Vg1 (first control voltage). For example, the control voltage Vg2 is set to 2 V, and the control voltage Vg1 is set to 1 V.

Next, a description is given of the relation among the inter-terminal withstand voltages of the MOS transistors constituting the level shift circuit 100 and the level shift circuit 200, inter-terminal application voltages applied between the terminals of the MOS transistors constituting the level shift circuit 100 and the level shift circuit 200, and the power supply voltage Vdd1.

For high speed operation, miniaturized MOS transistors are used for the MOS transistors constituting the level shift circuit 100 and the level shift circuit 200. In a MOS transistor, the more miniaturization advances, the lower the inter-terminal withstand voltage becomes.

Relations among a gate-source withstand voltage Vgs of a MOS transistor, a gate-drain withstand voltage Vgd of the MOS transistor, a gate-substrate withstand voltage Vgb of the MOS transistor, and a drain-source withstand voltage Vds of the MOS transistor are expressed as follows:

Vgb≥Vgs=Vgd>Vds. (1)

Thus, the drain-source withstand voltage Vds is the lowest among the inter terminal withstand voltages of the MOS transistor.

To allow the level shift circuit 100 and the level shift circuit 200 to operate normally, the inter-terminal application voltage Vapp1 needs to be set to be smaller than any of the inter-terminal withstand voltages of the MOS transistor (e.g., the drain-source withstand voltage Vds of the MOS transistor) as expressed below:

Vgb, Vgs, Vgd, Vds>Vapp1. (2)

A description is given of a case where a miniaturized MOS transistor with a drain-source withstand voltage Vds of 3V for example is used for high speed operation of the level shift circuit.

In the level shift circuit 200 of the comparative example, the inter-terminal application voltage Vapp1 applied to each of the MOS transistor PMT1, the MOS transistor PMT3, the MOS transistor NMT2, and the MOS transistor NMT4 is at a maximum of 3.3 V (the same level as the power supply voltage Vdd1) and thus exceeds the drain-source withstand voltage Vds. Then, there is a risk of breakage or degradation in reliability of the level shift circuit 200.

By contrast, in the level shift circuit 100 of the embodiment, the MOS transistor PMT2 and the MOS transistor NMT1 connected in series are provided between the cross-coupled circuit 1 and the MOS transistor NMT2, and the MOS transistor PMT4 and the MOS transistor NMT3 connected in series are provided between the cross-coupled circuit 1 and the MOS transistor NMT4. The control voltage Vg1 is applied to the MOS transistor PMT2 and the MOS transistor PMT4 to turn on the MOS transistor PMT2 and the MOS transistor PMT4. The control voltage Vg2 is applied to the MOS transistor NMT1 and the MOS transistor NMT3 to turn on the MOS transistor NMT1 and the MOS transistor NMT3. Thus, due to the split between the node N1 and the node N3 and between the node N4 and the node N6, the inter-terminal application voltage Vapp1 applied to each of the MOS transistors is decreased.

As expressed by

Vapp1>Vdd1, (2)

the inter-terminal application voltage Vapp1 at the same level as the power supply voltage Vdd1 is not applied to the MOS transistors constituting the level shift circuit 100. Thus, the level shift circuit 100 can operate normally.

As described above, the level shift circuit 100 of the embodiment is provided with the cross-coupled circuit 1, the inverter INV1, the MOS transistors NMT1 to NMT4, the MOS transistor PMT2, and the MOS transistor PMT4. The MOS transistor PMT2 and the MOS transistor NMT1 connected in series are provided between the cross-coupled circuit 1 and the MOS transistor NMT2, and the MOS transistor PMT4 and the MOS transistor NMT3 connected in series are provided between the cross-coupled circuit 1 and the MOS transistor NMT4. The control voltage Vg1 is applied to the control terminal (gate) of the MOS transistor PMT2 and to the control terminal (gate) of the MOS transistor PMT4. The control voltage Vg2 is applied to the control terminal (gate) of the MOS transistor NMT1 and to the control terminal (gate) of the MOS transistor NMT3. The inter-terminal application voltage applied to the MOS transistors is thus split and reduced.

Thus, even when miniaturized transistors are used as the MOS transistors constituting the level shift, circuit 100, the level shift circuit 100 does not break or degrade in reliability and can achieve high speed operation.

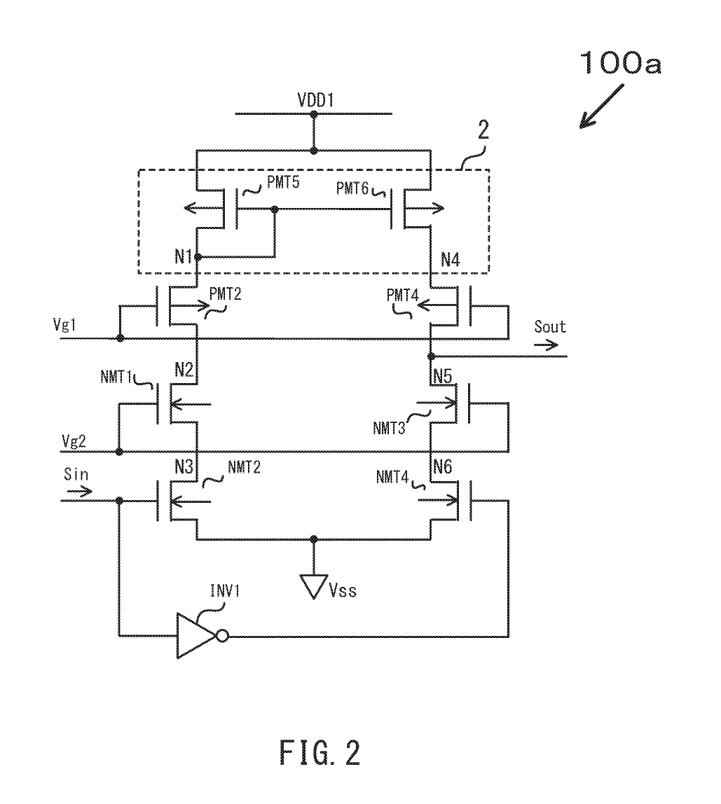

Although the level shift circuit 100 of the first embodiment uses the cross-coupled circuit 1, the invention is not necessarily limited to the this case. For example, a current mirror circuit 2 may be used, like a level shift circuit 100a of a first modification shown in FIG. 2. Specifically, the current mirror circuit 2 is configured with a MOS transistor PMT5 and a MOS transistor PMT6.

The MOS transistor PMT5 (first load transistor) is a P-channel MOS transistor. The MOS transistor PMT5 has one end (source) supplied with the power supply voltage Vdd1 from the power supply (high-potential power supply) VDD1 and the other end (drain) connected to a control terminal (gate) of the MOS transistor PMT5 and to the node N1.

The MOS transistor PMT6 (second load transistor) is a P-channel MOS transistor. The MOS transistor PMT6 has one end (source) supplied with the power supply voltage Vdd1 from the power supply (high-potential power supply) VDD1, a control terminal (gate) connected to the node N1 and to the control terminal (gate) of the MOS transistor PMT5, and the other end (drain) connected to the node N4.

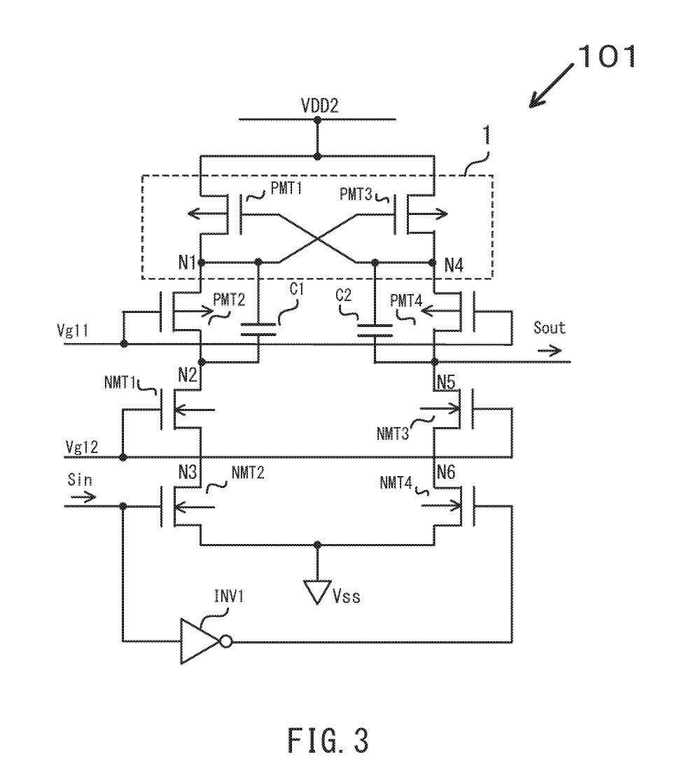

A level shift circuit according to a second embodiment will be described with reference to FIG. 3. FIG. 3 is a circuit diagram showing the level shift circuit.

The level shift circuit of the second embodiment is provided with two MOS transistors connected in series between a cross-coupled circuit and a MOS transistor to which an input signal is inputted, two MOS transistors connected in series between the cross-coupled circuit and a MOS transistor to which an inverted signal of the input signal is inputted, a first capacitor between a node N1 and a node N2, and a second capacitor between a node N4 and a node N5. The second embodiment improves the signal rise characteristics and the signal fall characteristics while reducing the inter-terminal application voltage applied between the terminals of each MOS transistor.

Hereinbelow, the same constituent portions as those in the first embodiment are denoted by the same reference numerals as used in the first embodiment and will not be described again. Only different portions will be described.

As shown in FIG. 3, a level shift circuit 101 of the embodiment includes the cross-coupled circuit 1, the inverter INV1, a capacitor C1, a capacitor C2, the MOS transistors NMT1 to NMT4, the MOS transistor PMT2, and the MOS transistor PMT4. The level shift circuit 101 is supplied with a power supply voltage Vdd2 from a power supply (high-potential power supply) VDD2, boosts the voltage of an input signal Sin, and outputs an output signal Sout whose high-level voltage is at the power supply voltage Vdd2.

The cross-coupled circuit 1 is supplied with the power supply voltage Vdd2 from the power supply (high-potential power supply) VDD2. A control voltage Vg11 (first control voltage) is applied to the control terminal (gate) of the MOS transistor PMT2 and to the control terminal (gate) of the MOS transistor PMT4. A control voltage Vg12 (second control voltage) is applied to the control terminal (gate) of the MOS transistor NMT1 and to the control terminal (gate) of the MOS transistor NMT3.

Here, the power supply voltage Vdd2 is set to 5 V. The control voltage Vg12 (second control voltage) is set to be higher than the control voltage Vg11 (first control voltage). For example, the control voltage Vg12 is set to 3V, and the control voltage Vg11 is set to 1.5 V.

The capacitor i has one end connected to the node N1 and the other end connected to the node N2. The capacitor C2 has one end connected to the node N4 and the other end connected to the node N5. The capacitor C1 and the capacitor C2 are set to have the same capacitance value.

During the operation of the level shift circuit 101, the capacitor assists (accelerates) a voltage drop at the node N1 while the voltage at the node N2 is dropping, suppressing a rise in the voltage between the node and the node N2. During the operation of the level shift circuit 101, the capacitor C1 assists (accelerates) a voltage rise at the node N1 while the voltage at the node N2 is rising.

During the operation of the level shift circuit 1.01, the capacitor C2 assists (accelerates) a voltage drop at the node N4 while the voltage at the node N5 is dropping, suppressing a rise in the voltage between the node N4 and the node N5. During the operation of the level shift circuit 101, the capacitor C2 assists (accelerates) a voltage rise at the node N4 while the voltage at the node N5 is rising.

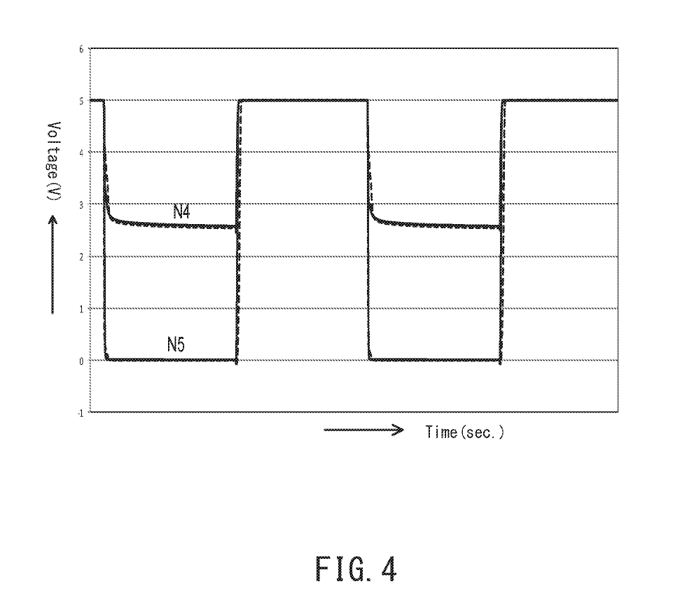

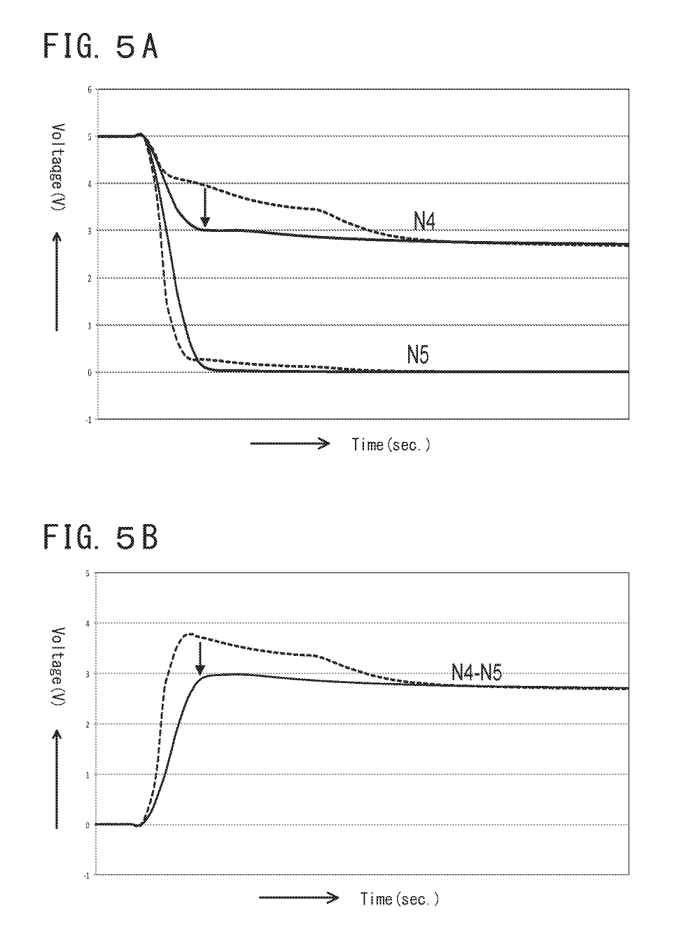

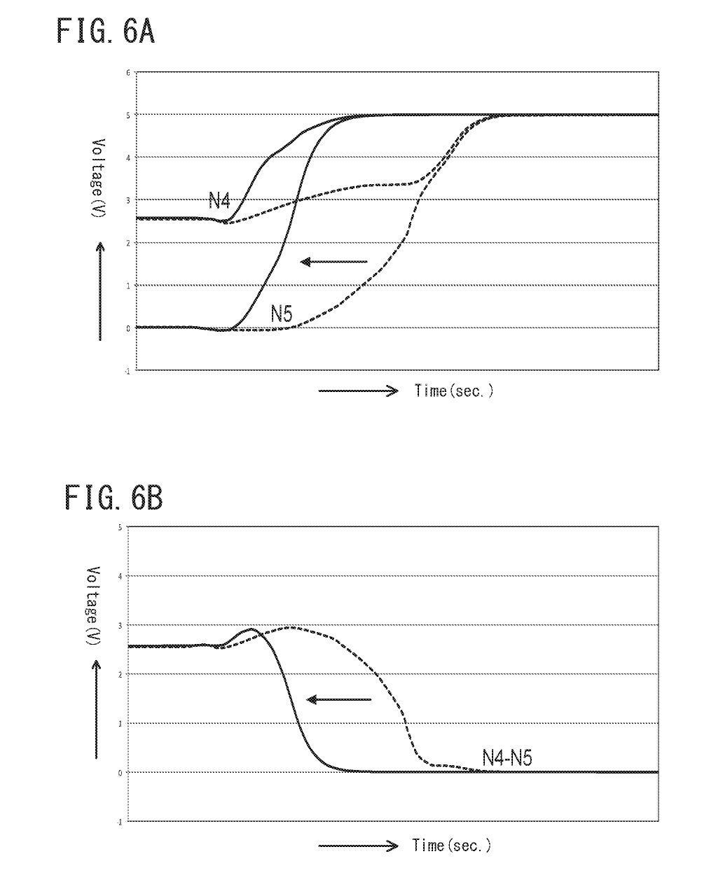

Next, operation of the level shift circuit will be described with reference to FIGS. 4, 5A, 5B, 6A, and 6B. FIG. 4 is a diagram showing signal waveforms at the node N4 and the node N5 of the level shift circuit. FIG. 5A is a diagram showing falls of the signal waveforms in. FIG. 4, and FIG. 5B is a diagram showing a change in voltage between the node N4 and the node N5 at the falls of the signal waveforms in FIG. 4. FIG. 6A is a diagram showing rises of the signal waveforms in FIG. 4, and FIG. 6B is a diagram showing a change in the voltage between the node N4 and the node N5 at the rises of the signal waveforms in FIG. 4. FIGS. 4, 5A, 5B, 6A, and 6B indicate the characteristics of the level shift circuit 100 of the first embodiment with a broken line and indicate the characteristics of the level shift circuit 101 of the embodiment with a solid line. Note that the level shift circuit 100 of the first embodiment is supplied with the power supply voltage Vdd2 from the power supply (high-potential power supply) VDD2. FIGS. 5A, 5B, 6A, and 6B show the horizontal axis (time) in a magnified manner relative to FIG. 4.

As shown in FIG. 4, in the level shift circuit 101 of the embodiment (indicated with a solid line) and the level shift circuit 100 of the first embodiment (indicated with a broken line), when the MOS transistor NMT4 is turned off, the node N4 and the node N5 (the output signal Sout) are set to the “Vdd2” level, and when the MOS transistor NMT4 is turned on, the node N4 is set to 2.7 V, and the node N5 (the output signal Sout) is set to the “Vss” level.

When the MOS transistor NMT4 is turned on from off (at a fall of a signal), as shown in FIG. 5A, a voltage drop at the node N4 is assisted (accelerated) more in the level shift circuit 101 of the embodiment than in the level shift circuit 100 of the first embodiment because the level shift circuit 101 of the embodiment is provided with the capacitor C2.

Thus, as shown in FIG. 5B, the level shift circuit 101 of the embodiment can suppress a rise in the voltage between the node N4 and the node N5 more than the level shift circuit 100 of the first embodiment, and allows the inter-terminal application voltage Vapp1 applied between the terminals of the MOS transistor PMT4 not to exceed the drain-source withstand voltage Vds (e.g., 3 V). By contrast, in the level shift circuit 100 of the first embodiment, the inter-terminal application voltage Vapp1 applied between the terminals of the MOS transistor PMT4 exceeds the drain-source withstand voltage Vds.

When the MOS transistor NMT4 is turned off from on (at a rise of a signal), as shown in FIG. 6A, a voltage rise at the node N4 is assisted (accelerated) more in the level shift circuit 101 of the embodiment than in the level shift circuit 100 of the first embodiment because the level shift circuit 101 of the embodiment is provided with the capacitor C2.

Thus, as shown in FIG. 6B, the level shift circuit 101 of the embodiment can suppress a rise in the voltage between the node N4 and the node N5 more than the level shift circuit 100 of the first embodiment, and allows the inter-terminal application voltage Vapp1 applied between the terminals of the MOS transistor PMT4 not to exceed the drain-source withstand voltage Vds (e.g., 3 V).

Although only the advantageous effects of disposing the capacitor C2 are described above using the FIGS. 4, 5A, 5B, 6A, and 6B, disposing the capacitor C1 can similarly achieve improvement in the signal falls and rises at the node N1 and the node N2 and suppression of the inter-terminal application voltage Vapp1 applied between the terminals of the MOS transistor PMT2.

Further, although the above describes the voltage applied to the terminals of the MOS transistor PMT4 (the node N4 and the node N5) and the voltage between the terminals (the node N4 and the node N5) using FIGS. 4, 5A, 5B, 6A, and 6B, the inter-terminal application voltage Vapp1 can be similarly suppressed not to exceed the inter-terminal withstand voltages of the other MOS transistors constituting the level shift circuit 101.

As described above, the level shift circuit 101 of the embodiment is provided with the cross-coupled circuit 1, the inverter INV1, the capacitor C1, the capacitor C2, the MOS transistors NMT1 to NMT4, the MOS transistor PMT2, and the MOS transistor PMT4. The capacitor C1 has one end connected to the node N1 and the other end connected to the node N2. The capacitor C2 has one end connected to the node N4 and the other end connected to the node N5. The cross-coupled circuit 1 is supplied with the power supply voltage Vdd2 from the power supply (high-potential power supply) VDD2. The control voltage Vg11 (first control voltage) is applied to the control terminal (gate) of the MOS transistor PMT2 and to the control terminal (gate) of the MOS transistor PMT4. The control voltage Vg12 (second control voltage) is applied to the control terminal (gate) of the MOS transistor NMT1 and to the control terminal (gate) of the MOS transistor NMT3.

Thus, even when the power supply voltage is higher than that in the first embodiment, the level shift circuit 101 does not break or degrade in reliability and can achieve high speed operation.

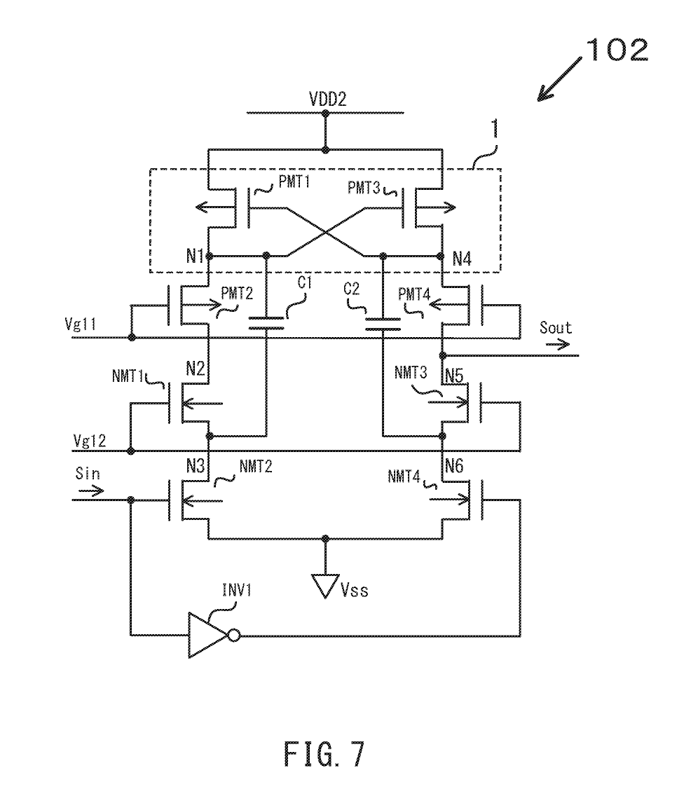

A level shift circuit according to a third embodiment will be described with reference to FIG. 7. FIG. 7 is a circuit diagram showing the level shift circuit.

The level shift circuit. of the third embodiment is provided with two MOS transistors connected in series between a cross-coupled circuit and a MOS transistor to which an input signal is inputted, two MOS transistors connected in series between the cross-coupled circuit and a MOS transistor to which an inverted signal of the input signal is inputted, a first capacitor between a node N1 and a node N3, and a second capacitor between a node N4 and a node N6. The third embodiment improves the signal rise characteristics and the signal fall characteristics while reducing the inter-terminal application voltage applied between the terminals of each MOS transistor.

Hereinbelow, the same constituent portions as those in the first embodiment are denoted by the same reference numerals as used in the first embodiment and will not be described again. Only different portions will be described.

As shown in FIG. 7, a level shift circuit 102 of the embodiment includes the cross-coupled circuit 1, the inverter INV1, the capacitor C1, the capacitor C2, the MOS transistors NMT1 to NMT4, the MOS transistor PMT2, and the MOS transistor PMT4.

The capacitor C1 has one end connected to the node N1 and the other end connected to the node N3. The capacitor C2 has one end connected to the node N4 and the other end connected to the node N6. The capacitor C1 and the capacitor C2 are set to have the same capacitance value.

During the operation of the level shift circuit 102, the capacitor C1 assists (accelerates) a voltage drop at the node N1 while the voltage at the node N3 is dropping, suppressing a rise in the voltage between the node N1 and the node N3. During the operation of the level shift circuit 102, the capacitor C1 assists (accelerates) a voltage rise at the node N1 while the voltage at the node N3 is rising.

During the operation of the level shift circuit 102, the capacitor C2 assists (accelerates) a voltage drop at the node N4 while the voltage at the node N6 is dropping, suppressing a rise in the voltage between the node N4 and the node N6. During the operation of the level shift circuit 102, the capacitor C2 assists (accelerates) a voltage rise at the node N4 while the voltage at the node N6 is rising.

As described above, the level shift circuit 102 of the embodiment is provided with the cross-coupled circuit 1, the inverter INV1, the capacitor C1, the capacitor C2, the MOS transistors NMT1 to NMT4, the MOS transistor PMT2, and the MOS transistor PMT4. The capacitor C1 has one end connected to the node N1 and the other end connected to the node N3. The capacitor C2 has one end connected to the node N4 and the other end connected to the node N6.

Thus, the level shift circuit 102 of the embodiment produces advantageous effects similar to those produced by the first and second embodiments.

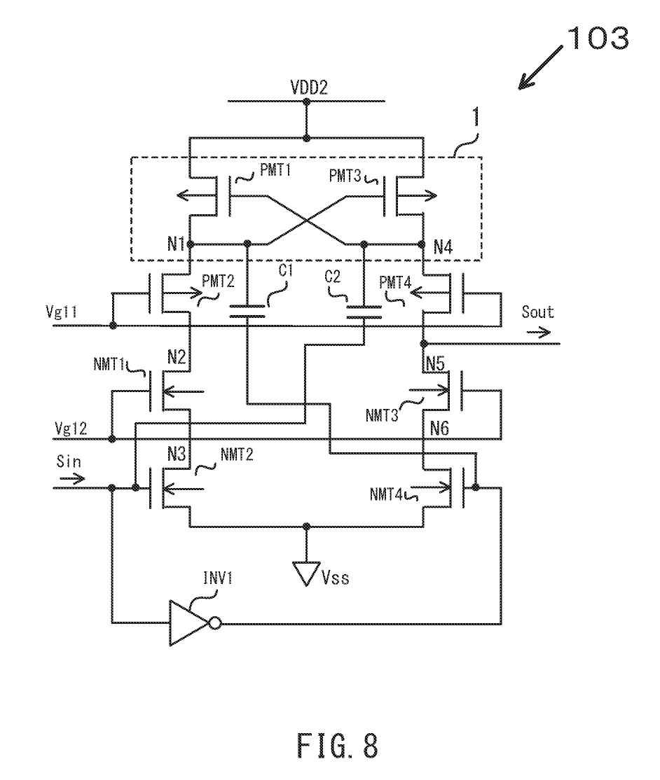

A level shift circuit according to a fourth embodiment will be described with reference to FIG. 8. FIG. 8 is a circuit diagram showing the level shift circuit.

The level shift circuit of the fourth embodiment is provided with two MOS transistors connected in series between a cross-coupled circuit and a MOS transistor to which an input signal is inputted, two MOS transistors connected in series between the cross-coupled circuit and a MOS transistor to which an inverted signal of the input, signal is inputted, a first capacitor between a node N1 and a control terminal of the MOS transistor to which the input signal is inputted via an inverter, and a second capacitor between a node N4 and a control terminal of the MOS transistor to which the input signal is inputted. The fourth embodiment improves the signal rise characteristics and the signal fall characteristics while reducing the inter-terminal application voltage applied between the terminals of each MOS transistor.

Hereinbelow, the same constituent portions as those in the first embodiment are denoted by the same reference numerals as used in the first embodiment and will not be described again. Only different portions will be described.

As shown in FIG. 8, a level shift circuit 103 of the embodiment includes the cross-coupled circuit 1, the inverter INV1, the capacitor C1, the capacitor C2, the MOS transistors NMT1 to NMT4, the MOS transistor PMT2, and the MOS transistor PMT4.

The capacitor C1 has one end connected to the node N1 and the other end connected to the control terminal (gate) of the MOS transistor NMT4. The capacitor C2 has one end connected to the node N4 and the other end connected to the control terminal (gate) of the MOS transistor NMT2. The capacitor C1 and the capacitor C2 are set to have the same capacitance value.

During the operation of the level shift circuit 103, the capacitor C1 assists (accelerates) a voltage drop at the node N1 while the voltage at the node N3 is dropping, suppressing a rise in the voltage between the node N1 and the node N3. During the operation of the level shift circuit 103, the capacitor C1 assists (accelerates) a voltage rise at the node N1 while the voltage at the node N3 is rising.

During the operation of the leve1 shift circuit 103, the capacitor C2 assists (accelerates) a voltage drop at the node N4 while the voltage at the node N6 is dropping, suppressing a rise in the voltage between the node N4 and the node N6. During the operation of the level shift circuit 103, the capacitor C2 assists (accelerates) a voltage rise at the node N4 while the voltage at the node N6 is rising.

As described above, the level shift circuit 103 of the embodiment is provided with the cross-coupled circuit 1, the inverter the capacitor the capacitor C2, the MOS transistors NMT1 to NMT4, the MOS transistor PMT2, and the MOS transistor PMT4. The capacitor C1 has one end connected to the node N1 and the other end connected to the control termina1 (gate) of the MOS transistor NMT4. The capacitor C2 has one end connected to the node N4 and the other end connected to the control terminal (gate) of the MOS transistor NMT2.

Thus, the level shift circuit 103 of the fourth embodiment produces advantageous effects similar to those produced by the first and second embodiments.

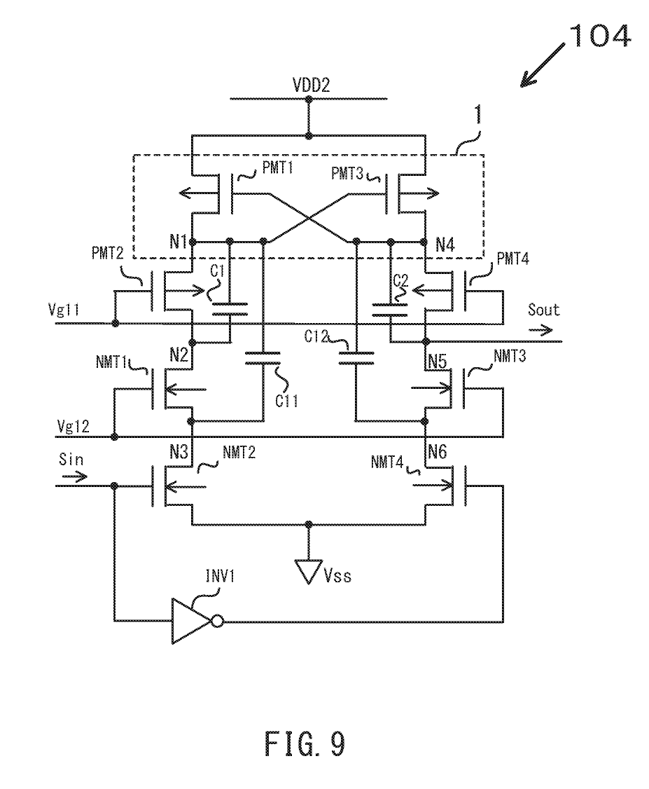

A level shift circuit according to a fifth embodiment will be described with reference to FIG. 9. FIG. 9 is a circuit diagram showing the level shift circuit.

The level shift circuit of the fifth embodiment is provided. with two MOS transistors connected. in series between a cross-coupled circuit and a MOS transistor to which an input signal is inputted, two MOS transistors connected in series between the cross-coupled circuit and a MOS transistor to which an inverted signal of the input signal is inputted, a first capacitor between a node N1 and a node N2, a second capacitor between a node N4 and a node N5, a third capacitor between the node N1. and a node N3, and a fourth capacitor between the node N4 and a node N6. The fifth embodiment improves the signal rise characteristics and the signal fall characteristics while reducing the inter-terminal application voltage applied between the terminals of each MOS transistor.

Hereinbelow, the same constituent portions as those in the second embodiment are denoted. by the same reference numerals as used in the second embodiment and will not be described again. Only different portions will be described.

As shown in FIG. 9, a level shift circuit 104 of the embodiment includes the cross-coupled circuit 1, the inverter INV1, the capacitor C1, the capacitor C2, a capacitor C11, a capacitor C12, the MOS transistors NMT1 to NMT4, the MOS transistor PMT2, and the MOS transistor PMT4.

The capacitor C11 has one end connected to the node N1 and the other end connected to the node N3. The capacitor C12 has one end connected to the node N4 and the other end connected to the node N6. The capacitor C11 and the capacitor C12 are set to have the same capacitance value.

During the operation of the level shift circuit 104, the capacitor C11 assists (accelerates) a voltage drop at the node N1 while the voltage at the node N3 is dropping, suppressing a rise in the voltage between the node N1 and the node N3. During the operation of the level shift circuit 104, the capacitor C11 assists (accelerates) a voltage rise at the node N1 while the voltage at the node N3 is rising.

During the operation of the level shift circuit 104, the capacitor C12 assists (accelerates) a voltage drop at the node N4 while the voltage at the node N6 is dropping, suppressing a rise in the voltage between the node N4 and the node N6. During the operation of the level shift circuit 104, the capacitor C12 assists (accelerates) a voltage rise at the node N4 while the voltage at the node N6 is rising.

As described above, the level shift circuit 104 of the embodiment is provided with the cross-coupled circuit 1, the inverter INV1, the capacitor C1, the capacitor C2, the capacitor C11, the capacitor C12, the MOS transistors NMT1 to NMT4, the MOS transistor PMT2, and the MOS transistor PMT4. The capacitor C11 has one end connected to the node N1 and the other end connected to the node N3. The capacitor C12 has one end connected to the node N4 and the other end connected to the node N6.

Thus, the level shift circuit 104 of the fifth embodiment produces advantageous effects similar to those produced by the first and second embodiments.

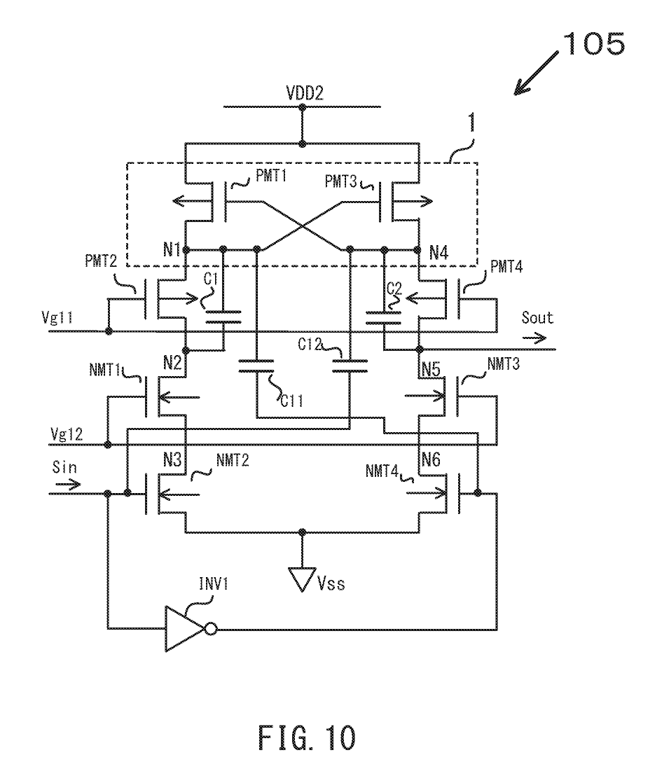

A level shift circuit according to a sixth embodiment will he described with reference to FIG. 10. FIG. 10 is a circuit, diagram showing the level shift circuit.

The level shift circuit of the sixth embodiment is provided with two MOS transistors connected in series between a cross-coupled circuit and a MOS transistor to which an input signal is inputted, two MOS transistors connected in series between the cross-coupled circuit, and a MOS transistor to which an inverted signal of the input signal is inputted, a first capacitor between a node N1 and a node N2, a second capacitor between a node N4 and a node N5, a third capacitor between the node N1 and a control terminal of the MOS transistor to which the input signal is inputted via an inverter, and a fourth capacitor between the node N4 and a control terminal of the MOS transistor to which the input signal is inputted. The sixth embodiment improves the signal rise characteristics and the signal fall characteristics while reducing the inter-terminal application voltage applied between the terminals of each MOS transistor.

Hereinbelow, the same constituent portions as those in the second embodiment are denoted by the same reference numerals as used in the second embodiment and will not be described again. Only different portions will be described.

As shown in FIG. 10, a level shift circuit 105 of the embodiment includes the cross-coupled circuit 1, the inverter INV1, the capacitor C1, the capacitor C2, a capacitor C11, a capacitor C12, the MOS transistors NMT1 to NMT4, the MOS transistor PMT2, and the MOS transistor PMT4.

The capacitor C11 has one end connected to the node N1 and the other end connected to the control terminal (gate) of the MOS transistor NMT4. The capacitor C12 has one end connected to the node N4 and the other end. connected to the control terminal (gate) of the MOS transistor NMT2. The capacitor C11 and the capacitor C12 are set have the same capacitance value.

The level shift circuit 105 improves the signal rise characteristics and the signal fall characteristics while reducing the inter-terminal application voltage applied between the terminals of each of the MOS transistors PMT1 to PMT4 and the MOS transistors NMT1 to NMT4, owing to the capacitor C1, the capacitor C2, the capacitor C11, and the capacitor C12.

As described above, the level shift circuit 105 of the embodiment is provided with the cross-coupled circuit 1, the inverter INV1, the capacitor C1, the capacitor C2, the capacitor C11, the capacitor C12, the MOS transistors NMT1 to NMT4, the MOS transistor PMT2 and the MOS transistor PMT4.

Thus, the level shift circuit 105 of the sixth embodiment produces advantageous effects similar to those produced by the first and second embodiments.

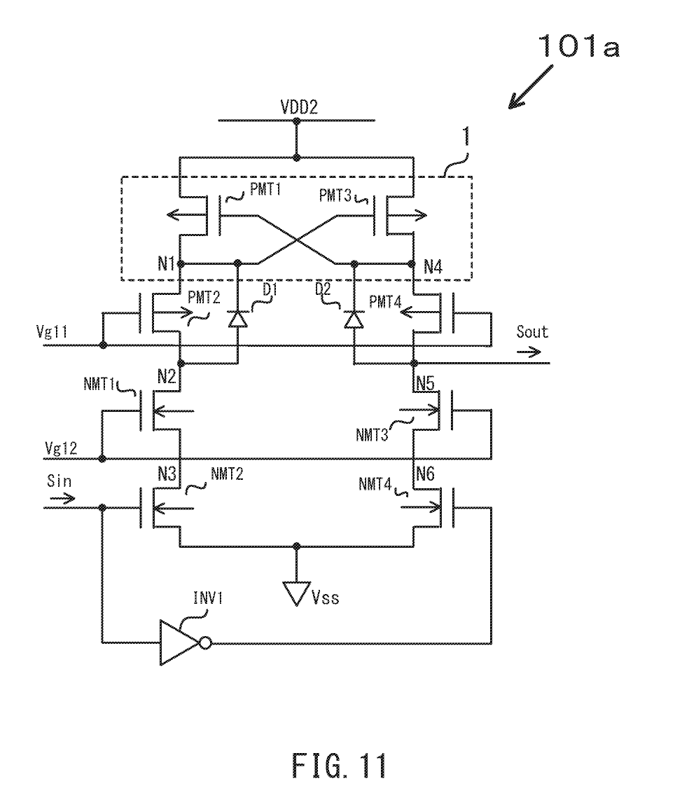

Although the level shift circuits of the first to sixth embodiments have been described, the invention is not necessarily limited to such embodiments. For example, diodes may be used in place of the capacitors, like a level shift circuit 1.01a of a second modification shown in FIG. 11.

Specifically, the level shift circuit 101a of the second modification is provided with a diode D1 and a diode D2. The diode D1 has a cathode connected to the node N1 and an anode connected to the node N2. The diode D2 has a cathode connected to the node N4 and an anode connected to the node N5. Like the capacitor C1 and the capacitor C2 of the second embodiment, the diode D1 and the diode D2 improve the signal rise characteristics and the signal fall characteristics while reducing the inter terminal application voltages.

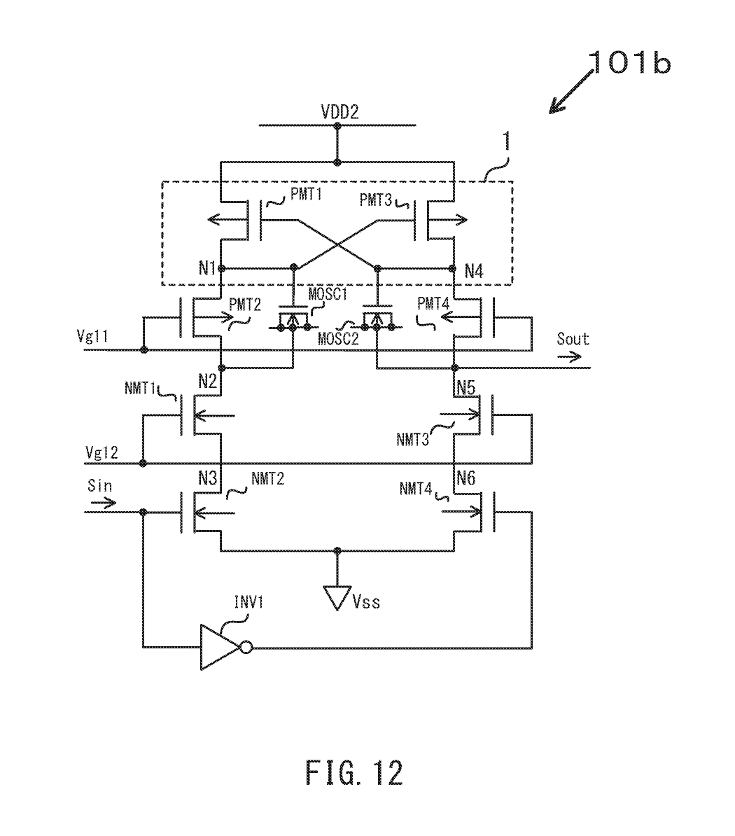

Further, MOS capacitors may be used in place of the capacitors, like a level shift circuit 101b of a third modification shown in FIG. 12.

Specifically, the level shift circuit 101b of the third modification is provided with a MOS capacitor MOSC1 and a MOS capacitor MOSC2. The MOS capacitor MOSC1 has a gate connected to the node N1 and a source, a drain, and a substrate connected to the node N2. The MOS capacitor MOSC2 has a gate connected to the node N4 and a source, a drain, and a substrate connected to the node N5. Like the capacitor C1 and the capacitor C2 of the second embodiment, the MOS capacitor MOSC1 and the MOS capacitor MOSC2 improve the signal rise characteristics and the signal fall characteristics while reducing the inter-terminal application voltages.

While certain embodiments have been described, these embodiments have been presented by way of example only, and are not intend to limit the scope of the inventions. Indeed, the novel embodiments described herein may be embodied in a variety of the other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A level shift circuit comprising:
a first transistor having a control terminal to which a first control voltage is applied;
a second transistor having a control terminal to which the first control voltage is applied;
a third transistor having a control terminal to which a second control voltage is applied and one end connected to one end of the first transistor;
a fourth transistor having a control terminal to which the second control voltage is applied and one end connected to one end of the second transistor;
a fifth transistor having a control terminal to which an input signal is inputted, one end connected to the other end of the third transistor, and the other end connected to a ground potential; and
a sixth transistor having a control terminal to which an inverted. signal of the input signal is inputted, one end connected to the other end of the fourth transistor, and the other end connected to the ground potential, wherein
the level shift circuit is supplied with a power supply voltage, boosts a voltage of the input signal, and outputs an output signal whose high-level voltage is at the power source voltage.

2. The level shift circuit according to claim 1, further comprising:
a first capacitor having one end connected to the one end of the first transistor and the other end connected to the other end of the first transistor; and
a second capacitor having one end connected to the one end of the second transistor and the other end connected to the other end of the second transistor.

3. The level shift circuit according to claim 2, wherein
during operation of the level shift circuit, each of the first to sixth transistors receives an inter-terminal application voltage between the one end and the other end, the inter-terminal application voltage being set to be lower than a withstand voltage between the one end and the other end.

4. The level shift circuit according to claim 2, further comprising:
a third capacitor having one end connected to the other end of the third transistor and the other end connected to the other end of the first transistor; and
a fourth capacitor having one end connected to the other end of the fourth transistor and the other end connected to the other end of the second transistor.

5. The level shift circuit according to claim 2, further comprising:
a third capacitor having one end connected to the control terminal of the sixth transistor and the other end connected to the other end of the first transistor; and
a fourth capacitor having one end connected to the control terminal of the fifth transistor and the other end connected to the other end of the second transistor.

6. The level shift circuit according to claim 1, further comprising:
a first capacitor having one end connected to the other end of the third transistor and. the other end connected to the other end of the first transistor; and
a second capacitor having one end connected to the other end of the fourth transistor and the other end connected to the other end of the second transistor.

7. The level shift circuit according to claim 6, wherein
during operation of the level shift circuit, each of the first to sixth transistors receives an inter-terminal application voltage between the one end and the other end., the inter-terminal application voltage being set to be lower than a withstand voltage between the one end and the other end.

8. The level shift circuit according to claim 1, further comprising:
a first capacitor having one end connected to the control terminal of the sixth transistor and the other end connected to the other end of the first transistor; and
a second capacitor having one end connected to the control terminal of the fifth transistor and the other end connected to the other end of the second transistor.

9. The level shift circuit according to claim 8, wherein
during operation of the level shift circuit, each of the first to sixth transistors receives an inter-terminal application voltage between the one end and the other end, the inter-terminal application voltage being set to be lower than a withstand voltage between the one end and the other end.

10. The level shift circuit according to claim 1, further comprising a cross-coupled circuit including
a first load transistor having one end supplied with the power supply voltage and the other end connected to the other end of the first transistor, and
a second load transistor having one end supplied with the power supply voltage, a control terminal connected to the other end of the first load transistor, and the other end connected to a control terminal of the first load transistor and to the other end of the second transistor.

11. The level shift circuit according to claim 10, wherein the first and second load transistors are P-channel MOS transistors,

12. The level shift circuit according to claim 1, further comprising a current mirror circuit including
a first load transistor having one end supplied with the power supply voltage and the other end connected to a control terminal of the first load transistor and to the other end of the first transistor, and
a second load transistor having one end supplied with the power supply voltage, a control terminal connected to the control terminal of the first load transistor, and the other end connected to the other end of the second transistor.

13. The level shift circuit according to claim 12, wherein
the first and second load transistors are P-channel MOS transistors

14. The level shift circuit according to claim 1, wherein
the second control voltage is higher than the first control voltage.

15. The level shift circuit according to claim 1, wherein
the first and second transistors are P-channel MOS transistors, and
the third to sixth transistors are N-channel MOS transistors.

16. The level shift circuit according to claim 1, further comprising:
a first diode having an anode connected to the one end of the first transistor and a cathode connected to the other end of the first transistor; and
a second diode having an anode connected to the one end of the second transistor and a cathode connected to the other end of the second transistor.

17. The level shift circuit according to claim 1, further comprising:
a first MOS capacitor having a source, a substrate, and a drain connected to the one end of the first transistor and a gate connected to the other end of the first transistor; and
a second MOS capacitor having a source, a substrate, and a drain connected to the one end of the second transistor and a gate connected to the other end of the second transistor,
